(19) United States
(12) Patent Application Publication
(10) Pub. No.: US 2011/0241831 A1
(43) Pub. Date: Oct. 6, 2011

(54) STORAGE SYSTEM

(75) Inventors: Jarkko Mäkiranta, Siuro (FI); Kari Kyyny, Guangzhou (CN); Laurentiu Barna, Nokia (FI); Kari Kymäläinen, Nummela (FI); Mikko Martikainen, Espoo (FI)

(73) Assignee: MARISENSE OY, Vantaa (FI)

(21) Appl. No.: 13/061,827

(22) PCT Filed: Sep. 3, 2008
(86) PCT No.: PCT/FI08/50488

§ 371 Date: Jun. 10, 2011

(51) Int. Cl. G06F 7/00

(52) U.S. Cl. 340/5.92

(57) ABSTRACT

A storage system (500) comprises a storage unit (100), wherein said storage unit (100) has sites (S1a, S1b) for accommodating two or more of said objects (G1), said storage unit (100) further comprising one or more capacitive proximity sensors (50) arranged to detect the presence of said objects (G1) in the vicinity of said sites (S1a, S1b). The storage unit may be e.g. a shelving in a retail store. The filling ratio (N/Nmax) or the number (N) of objects on the shelves (90) may be monitored in real time. Consequently, out-of-shelf situations may be effectively avoided.

### FIELD OF THE INVENTION

The present invention relates to monitoring the presence of objects stored by a storage unit.

### BACKGROUND

Out-of-stock situations, and in particular out-of-shelf situations may cause problems in retail shops. A shelf monitoring system may be arranged to monitor the filling ratio of shelves and to prevent out-of-shelf situations.

US 2008/077510 discloses the use of a camera arranged to monitor the status of shelves.

U.S. Pat. No. 5,703,785 discloses the use of light emitting diodes and photodetectors arranged to monitor the status of shelves.

U.S. Pat. No. 5,671,362 discloses the use of weight-sensitive transducers arranged to monitor the status of shelves.

### SUMMARY

An object of the invention is to provide a storage system capable of monitoring the number of items stored by a storage unit.

An object of the invention is to provide a method for monitoring the number of items stored by a storage unit.

According to a first aspect of the invention, there is provided a method according to claim 1.

According to a first aspect of the invention, there is provided a computer program according to claim 11.

According to a first aspect of the invention, there is provided a computer-readable medium according to claim 12.

According to a first aspect of the invention, there is provided a storage system according to claim 13.

The storage unit may be arranged to store two or more objects. The storage unit comprises at least one capacitive proximity sensor to monitor the number of objects in or on said storage unit.

The storage unit may be e.g. a cabinet, shelf or shelving in a retail store, accessible to customers. The storage unit may also be a shelving in a factory or repair workshop.

A capacitive proximity sensor comprises two electrode plates. Presence of objects (i.e. countable bodies) may be detected by measuring a change of capacitance between the two electrode plates. The presence of an object causes a change in the dielectric constant between the plates, which in turn causes a change in the capacitance formed by said two plates, when compared with a situation where the object is far away from said plates.

The signal provided by a capacitive proximity sensor can be used as a qualitative on/off indicator, i.e. to distinguish a situation where an object is on a shelf from a situation where said object has been taken away from the shelf.

Alternatively, the signal provided by a capacitive proximity sensor can be used as a quantitative indication of the filling ratio of a shelf, i.e. to estimate the ratio of the number of objects on the shelf to a maximum number of said objects which can be accommodated by said shelf.

The capacitive proximity sensor may be easily fabricated or adapted to match with various different forms and sizes of shelves. A capacitive proximity sensor may be thin and/or flexible. In certain cases, capacitive proximity sensor may be easily cut to a desired form.

The capacitive proximity sensor may be cheaper to manufacture than a pressure-sensitive sensor or a device which optically detects the presence of objects. The capacitive proximity sensor may also be cheaper to replace if damaged e.g. due to impact or scratching.

For comparison, camera-based monitoring is limited to objects which are visible. The capacitive sensor allows monitoring of objects which are on the back side of a shelf or behind other objects. The operation of the capacitive proximity sensor is not affected by bright illumination typically present in supermarkets. On the other hand, the capacitive proximity sensor performs well in complete darkness or in places where it is difficult to arrange illumination.

The capacitive proximity sensor may also operate satisfactorily in dirty and/or dusty environments.

The capacitive proximity sensor may also satisfactorily operate in conditions where frozen dew is present, e.g. in deep-freezers of a supermarket. In those optical devices may be frosted and pressure-sensitive foils may be covered with a stiff layer of ice.

The filling ratio may be monitored in real time. Efficient replenishment of the goods can be arranged by using the storage system with capacitive proximity sensors.

The embodiments of the invention and their benefits will become more apparent to a person skilled in the art through the description and examples given herein below, and also through the appended claims.

### BRIEF DESCRIPTION OF THE DRAWINGS

In the following examples, the embodiments of the invention will be described in more detail with reference to the appended drawings, in which

FIG. 1 shows, in a cross-sectional view, a capacitive proximity sensor,

FIG. 2a shows an equivalent circuit of a capacitive proximity sensor,

FIG. 2b shows an equivalent circuit of a capacitive proximity sensor when a conductive object is located near the sensor,

FIG. 3 shows, in a three-dimensional view, a storage unit comprising a capacitive proximity sensor,

FIG. 4 shows, in a top view, a capacitive proximity sensor having interleaved electrode areas,

FIG. 5a shows, in a three-dimensional view, a capacitive proximity sensor attached to a vertical structure,

FIG. 5b shows, in a three-dimensional view, a capacitive proximity sensor arranged to detect objects in a volume between two shelves,

FIG. 6a shows, in a three-dimensional view, a shelving comprising different types of objects,

FIG. 6b shows, by way of example, a display view indicating the status of the shelving of FIG. 6a,

FIG. 7 shows, by way of example, temporal evolution of measured capacitance when objects are added and removed,

FIG. 8a shows, by way of example, a relationship between the filling ratio of objects and measured change of capacitance for glass bottles and aluminum-lined cardboard packages.

FIG. 8b shows, by way of example, a relationship between the filling ratio of objects and measured change of capacitance for metal cans and cardboard packages filled with a grain product,

FIG. 9 shows a flow chart for the calibration and use of a storage unit, wherein the storage unit is completely emptied and completely filled during the calibration,

FIG. 10 shows a flow chart for the use of a storage unit, wherein the operating parameters are retrieved from a database,

FIG. 11 shows a flow chart for the calibration and use of a storage unit, wherein the calibration comprises adding or removing at least one object,

FIG. 12a shows a block diagram of a storage system,

FIG. 12b shows a block diagram of a storage system arranged to communicate with a cashing system, a robot and/or a manufacturer,

FIG. 13 shows a block diagram of a storage system,

FIG. 14 shows several capacitive proximity sensors coupled to a multiplexer,

FIG. 15 shows, by way of example, software levels of a storage system,

FIG. 16 shows, in a cross-sectional view, a capacitive proximity sensor, wherein the surface of a shelf acts as a reference electrode,

FIG. 17 shows, in a three-dimensional view, a capacitive proximity sensor, wherein the surface of a shelf acts as a reference electrode,

FIG. 18a shows, in a three-dimensional view, a shelf comprising several independent capacitive proximity sensors,

FIG. 18b shows, in a three-dimensional view, capacitive proximity sensors having wider electrodes than the sensors of FIG. 18a,

FIG. 18c shows, in a three-dimensional view, capacitive proximity sensors, wherein the surface of a shelf acts as reference electrodes,

FIG. 19 shows, in a three-dimensional view, a capacitive proximity sensor arranged to monitor objects near the front side of a shelf,

FIG. 20 shows, in a three-dimensional view, a storage unit comprising sensors arranged as an array, and

FIG. 21 shows, in a three-dimensional view, making of a shelf which comprises an integrated capacitive proximity sensor.

All drawings are schematic.

### DETAILED DESCRIPTION

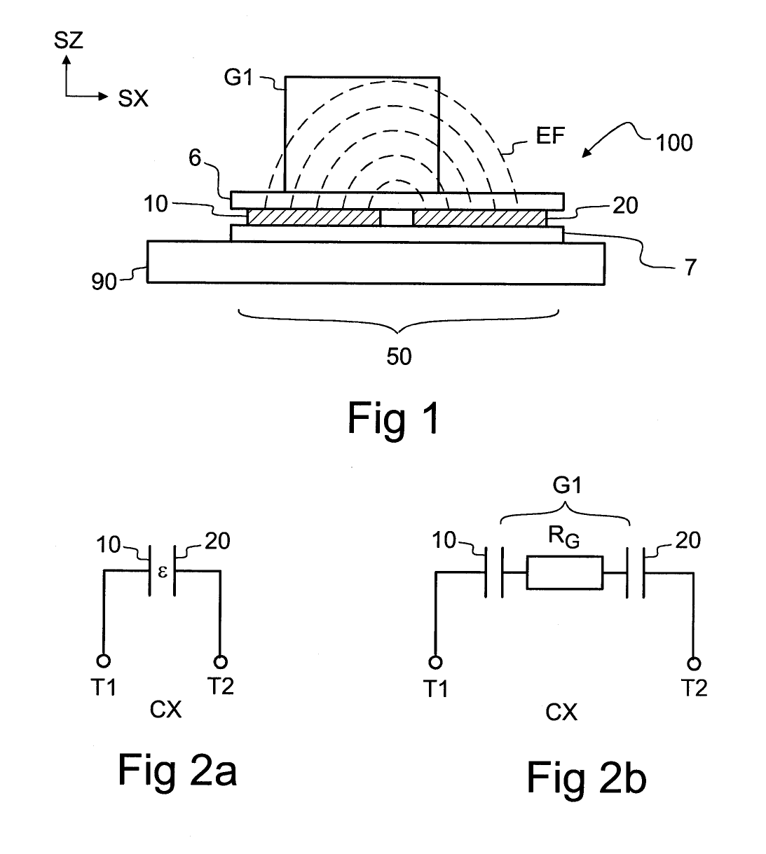

Referring to FIG. 1, a capacitive proximity sensor 50 may comprise a reference electrode 10 and a signal electrode 20 disposed on an electrically insulating substrate 7. The capacitive proximity sensor 50 may be attached e.g. onto a shelf 90 in order to form a storage unit 100.

The electrodes 10, 20 form a capacitive system together with the medium located between said electrodes. Said capacitive system CX has a capacitance value CX. The symbol CX is herein used to refer to the physical entity (capacitor) as well as to the measurable quantity (capacitance).

A voltage applied between the electrodes 10, 20 creates an electric field EF, which may interact with an object G1 positioned near the electrodes 10, 20. The object G1 may change the electric field EF. Thus, the proximity of an object G1 in the vicinity of the sensor 50 changes the capacitance CX of a capacitor formed by the reference electrode 10 and the signal electrode 20.

The sensor 50 may comprise an electrically insulating layer 6 in order to prevent contact between the object G1 and the electrodes 10, 20, i.e. to electrically insulate the object G1 from one of the electrodes 10, 20 or from both electrodes 10, 20.

The thickness of the insulating layer 6 may be e.g. in the range of 0.5 to 5 mm. The use of a thin insulating layer may improve the sensitivity of the sensor 50.

The insulating layer 6 may be opaque in order to make the electrodes 10, 20 invisible.

For an optimum spatial resolution and signal-to-noise ratio, the size of the electrodes 10, 20 may be in the same order of magnitude as the size of the objects G1 to be detected.

If the shelf 90 is made of an electrically insulating material, it may also act as the substrate 7. In that case the electrodes 10, 20 may be directly attached on the shelf 90.

The electrodes 10, 20 may also be embedded within the substrate 7 e.g. in order to improve durability and/or visual appearance.

The sensor 50 is preferably arranged such that distance between the electrodes 10, 20 is substantially constant during the operation of the sensor 50. Removal or addition of the object G1 may change the capacitance CX of the sensor 50 without substantially changing the between the electrodes 10, 20. In other words, the distance between electrodes may be substantially independent of pressure applied by the object G1.

This differentiates the capacitive proximity sensor 50 e.g. from a capacitive pressure or weight sensor where the change of the capacitance is substantially based on changing the distance between electrodes. The weight of the object G1 may compress a material between the electrodes of a pressure sensor and change the distance between the electrodes.

The capacitive proximity sensor 50 is capable of detecting the presence of the object G1 also without physical contact between the object G1 and the sensor 50.

The shelf 90 may also be metallic, i.e. electrically conductive. In that case the presence of the shelf 90 in the vicinity of the electrodes 10, 20 may reduce the sensitivity of the sensor 50. The thickness of the substrate 7 may be e.g. in the range of 0.5 to 2 mm in order to improve the sensitivity.

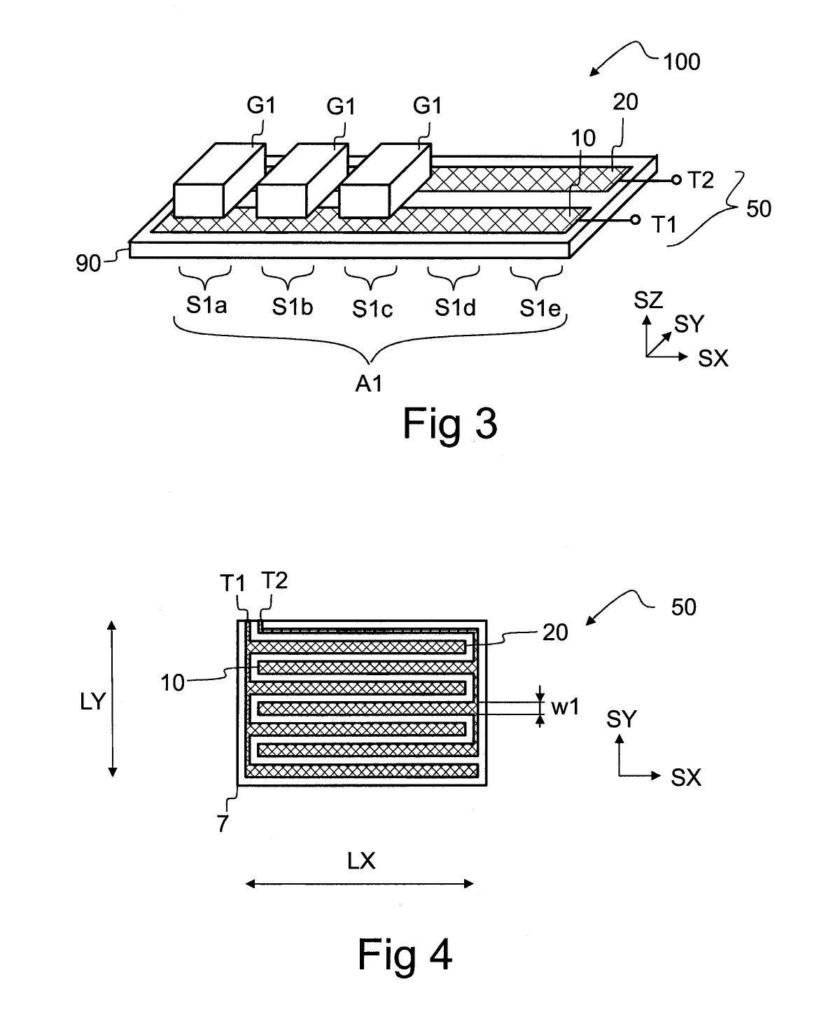

SX, SY, and SZ are orthogonal directions. The substrate 7 may be substantially planar. The substrate 7 may be in a plane defined by the direction SX and SY (see FIG. 3).

FIG. 2a shows an equivalent circuit of a capacitive proximity sensor when the object G1 is electrically insulating. The presence of the object G1 changes the dielectric permittivity ∈ between the electrodes 10, 20. The terminal T1 is coupled to the reference electrode 10 and the terminal T2 is coupled to the signal electrode 20.

FIG. 2b shows an equivalent circuit of a capacitive proximity sensor when the object G1 is electrically conductive. In that case the system may be understood to comprise two capacitors and a resistor connected in series. A first capacitor is formed between the reference electrode 10 and the surface of the electrically conductive object G1. A second capacitor is formed between the object G1 and the signal electrode 20. The internal resistance of the object G1 corresponds to a resistor R_{G}.

The capacitance CX of the sensor may be determined e.g. by varying a voltage coupled between the electrodes 10, 20, and by measuring corresponding variations in the current coupled to the electrodes 10, 20. For example, a substantially sinusoidal, rectangular or sawtooth voltage waveform may be coupled to the electrodes 10, 20. The frequency of the voltage may be e.g. in the range of 1 Hz to 10 MHz.

Referring to FIG. 3, a storage unit 100 may comprise a capacitive proximity sensor 50 attached on a shelf 90 to detect the presence of objects G1, G1b, G1c disposed on the shelf 90. In this case the shelf 90 has an area A1 which is suitable for accommodating five objects G1. The area A1 may be understood to consist of five sites S1a, S1b, S1c, S1d, and S1e, wherein each site is suitable for accommodating one object substantially similar to the object G1.

The storage unit 100 may comprise only one sensor 50 arranged to detect the number N of occupied sites S1a, S1b, S1c.

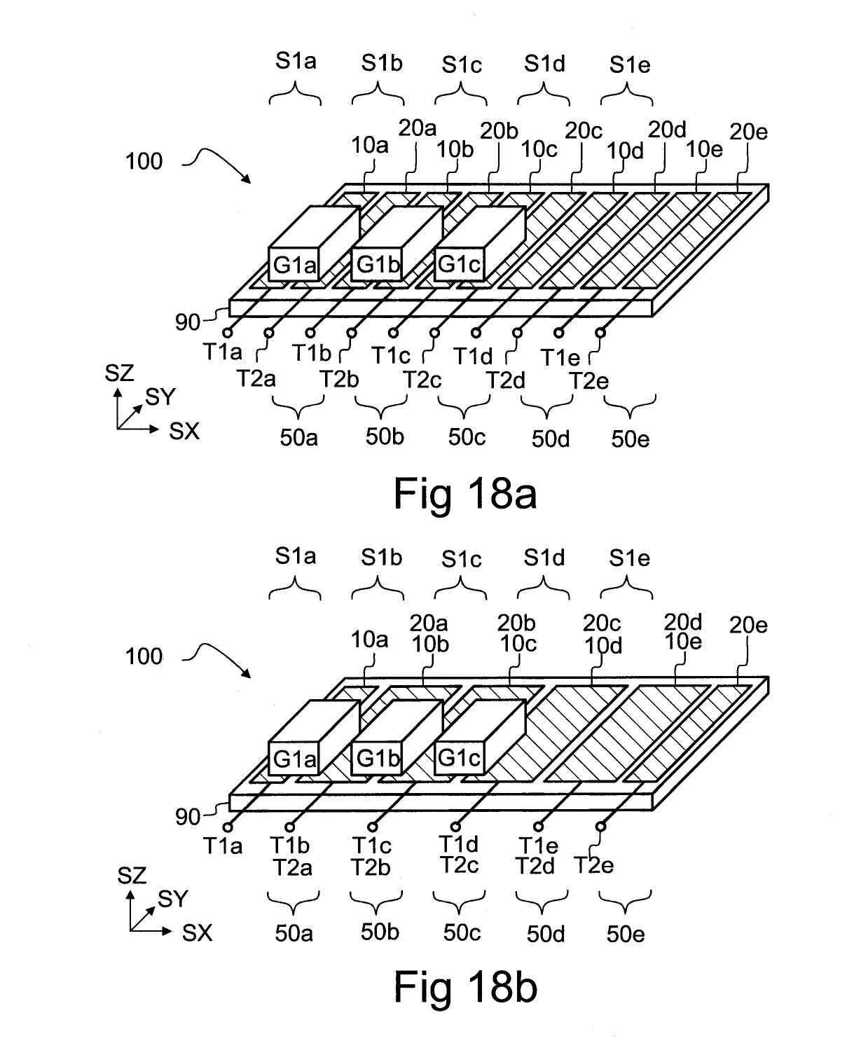

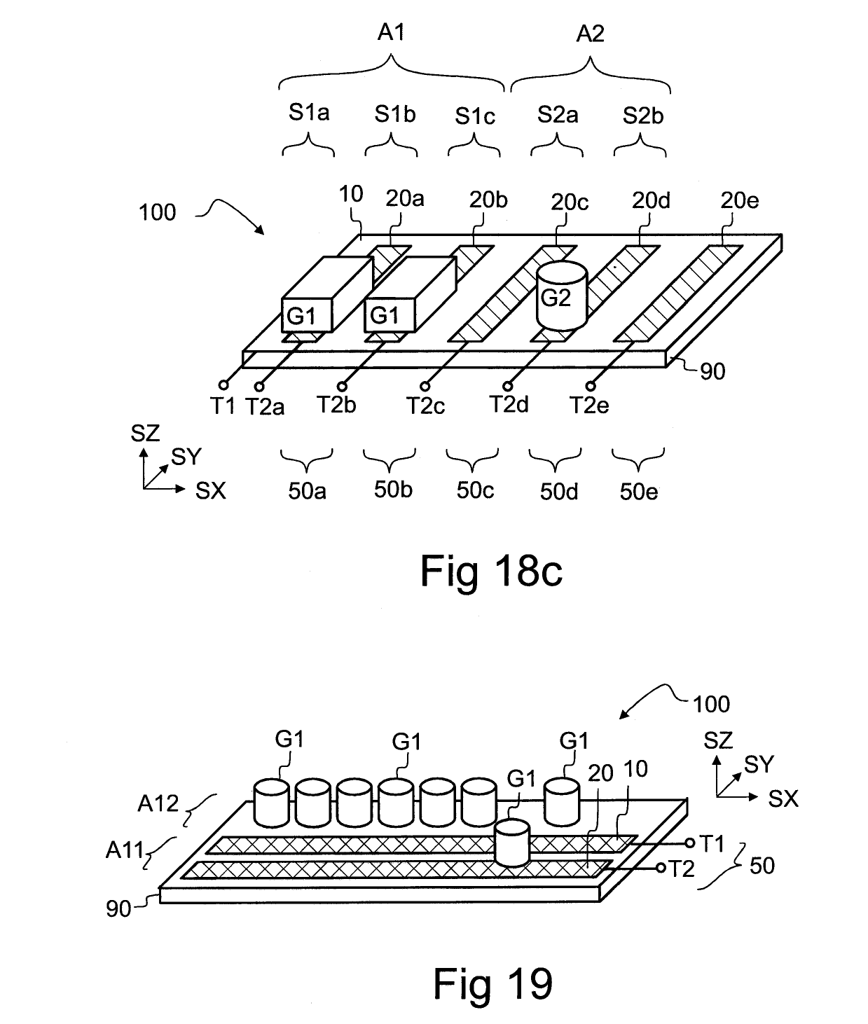

With only one sensor 50 is not typically possible to identify which ones of the sites S1a, S1b, S1c, S1d, and S1e are occupied. For that purpose several sensors 50 may be used (see e.g. FIG. 18a).

Referring to FIG. 4, each electrode 10, 20 of the sensor 50 may comprise a plurality of substantially longitudinal electrode areas, which are electrically connected together. The width w1 of the electrode areas (e.g. in the direction SX or SY) may be e.g. in the range of 2-20 mm, preferably in the range of 8-12 mm. Said electrode areas may be interleaved so as to improve the detection of small objects G1. The electrode areas may be substantially flat and/or substantially parallel.

The total width LX of the reference electrode 10 may be e.g. in the range of 10 to 100 mm, and the total depth LY of the reference electrode may be e.g. in the range of 200 to 500 mm.

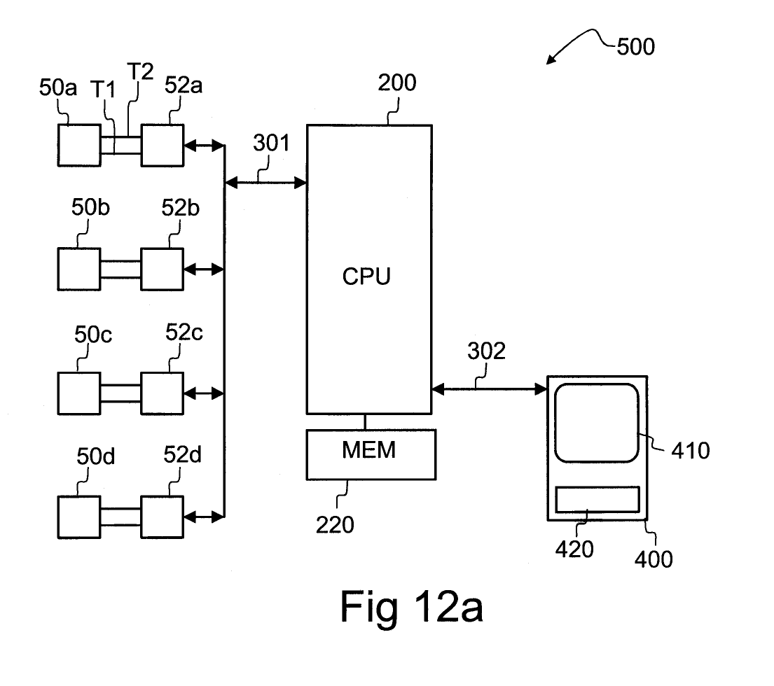

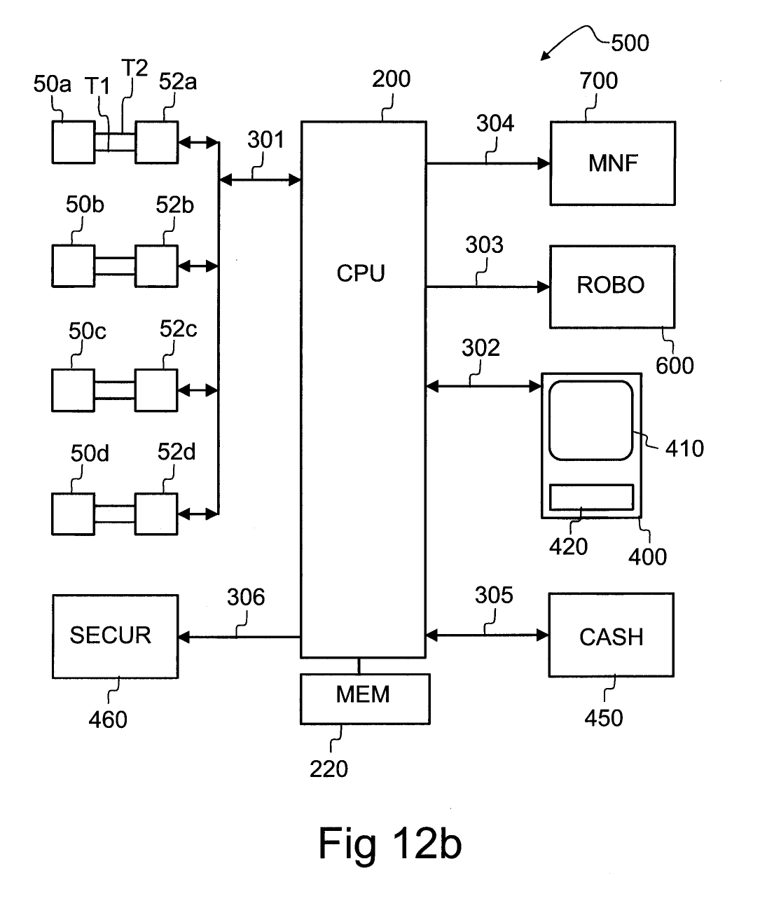

Electrical cables and/or a read-out unit (see FIG. 12a) may be connected to the terminal T1, T2 e.g. by one or more crimp connectors.

The electrodes of the sensor 50 may also have another form. For example, the sensor 50 may also have curved electrodes 10, 20, which are substantially concentric spirals.

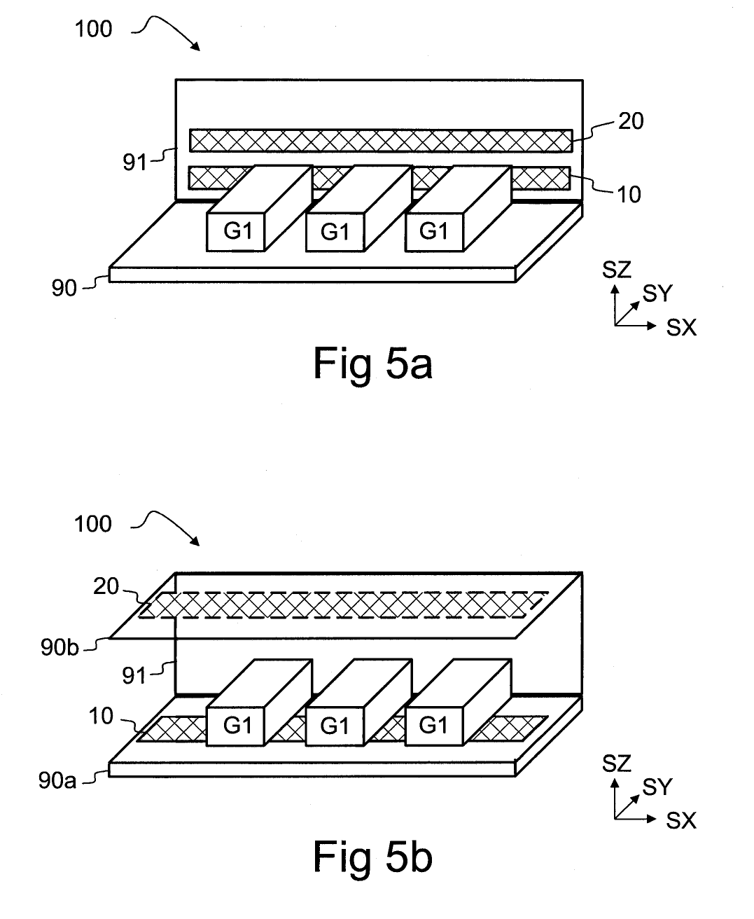

Referring to FIG. 5a, the electrodes 10, 20 of the sensor 50 may also be positioned behind the objects G1. The sensor 50 may be attached e.g. on a vertical supporting structure 91 of a shelf 90.

The sensor 50 may also be attached e.g. to the bottom side of a further structure, e.g. to another shelf which is supported above the objects G1. Referring to FIG. 5b, a lower shelf 90a of a shelving may comprise a first electrode 10, and an upper shelf 90b of said shelving may comprise a second electrode 20 of a capacitive proximity sensor 50. The electrodes 10, are arranged to monitor objects in a volume between the lower 90a and upper shelf 90b. In general, the electrodes 10, 20 of a sensor 50 may be arranged to detect objects in a volume between said electrodes 10, 20.

In a similar way, the electrodes 10, 20 may also be attached to opposite sides of a box or chest to detect objects in the box.

If a shelving comprises shelves in three or more levels, then the electrode or electrodes of a shelf in the middle may be used as a part of two different sensors 50. A lower sensor may comprise the electrodes 10, 20 of a lower shelf and the middle shelf. An upper sensor may comprise the electrodes 10, of an upper shelf and the middle shelf. The lower sensor detects objects disposed on the lower shelf, and the upper sensor detects objects disposed on the middle shelf. If the material of the shelf is electrically insulating, a single electrode may be used as a part of the upper and lower sensor. However, the upper and lower sides of the middle shelf may also have separate electrodes.

Instead of a shelf 90, or in addition to the shelf 90, the storage unit 100 may comprise other supporting means to support or hold the objects G1. The storage unit 100 may e.g. comprise one or more hooks or a magnetic plate to hang the objects G1 (not shown). Instead of a shelf 90, an open or lidded box may also be used, for example.

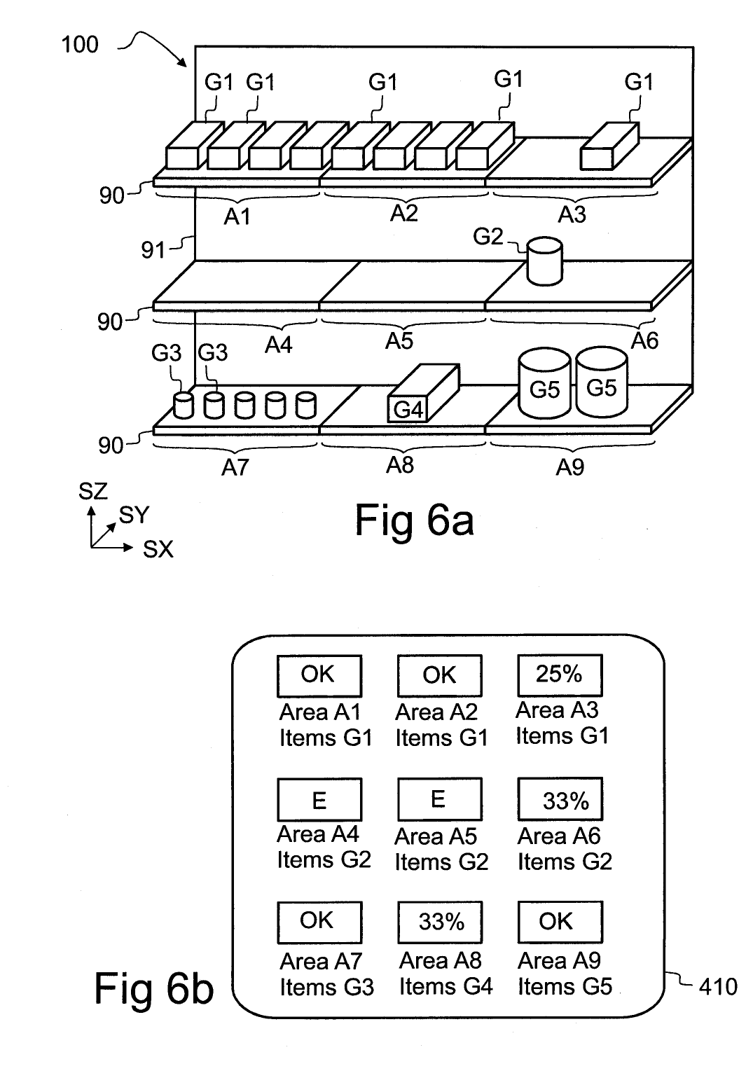

FIG. 6a shows a storage unit 100. The storage unit 100 may be a shelving, which comprises two or more shelves 90 in two or more levels. In case of FIG. 6a, the storage unit 100 is a shelving, which comprises shelves 90 in three levels. Each level, in turn, comprises three adjacent shelves 90.

Each shelf 90 corresponds to a separately monitored storage area A1, A2, A3, A4, A5, A6, A7, A8, or A9. Each shelf 90 may comprise a substantially independent capacitive proximity sensor 50 arranged to monitor the areas A1, A2, A3, A4, A5, A6, A7, A8, or A9 substantially separately. Each shelf 90 of FIG. 6a may comprise a sensor 50 shown e.g. in FIG. 3.

The uppermost level is allocated for objects of type G1. The middle level is allocated for objects of type G2. Each shelf plate 90 of the lowermost level is allocated for objects of the type G3, G4, and G5, respectively. The objects of the type G1 have substantially similar size, shape and composition. However, the objects G1 may have substantially different size, shape and/or composition when compared with the objects of type G2.

The sensors 50 of the storage unit 100 may be arranged to monitor the number of objects and/or the filling factor of each area A1. A filling factor N/Nmax refers to the ratio of the number N of objects on an area A1 to the maximum number Nmax of objects which can be accommodated on said area A1. The filling factor N/Nmax may also be interpreted to mean the ratio of the number N of sites S1a, S1b, S1c occupied by the objects G1 to the maximum number of sites S1a, S1b, S1c, S1d, S1e allocated for the objects G1.

FIG. 6b is a display view of a graphical display unit 410 indicating the status of the storage unit of FIG. 6a. A symbol OK may mean that the filling factor is greater than 50%. A symbol E (i.e. “empty”) may mean that the filling factor is smaller than 10%. The filling factors in the range of 10% to 40% may be indicated e.g. by numbers.

The display unit 410 may indicate that the status of the areas A1 and A2 allocated for the objects of the type G1 is OK, but the filling factor of the area A3 is only 25%. There is only one object G1 on the area A3 although the area A3 could accommodate up to four objects of the type G1.

The display unit 410 may indicate that the areas A4 and A5 allocated for the second type of objects G2 are empty, but the filling factor of the area A6 is 33%. There is only one object G2 on the area A6 although the area A6 could accommodate up to three objects of the type G2.

The display unit 410 may indicate that the area A7 reserved for the objects of the type G3 is full, the filling factor of the area A8 for products G4 is 33%, and the area A9 allocated for the products G5 is full.

Also dials or bars or different colors may be used to indicate the filling factor of each area. For example, red color may be used to indicate an empty shelf 90 and green color may be used to indicate a full shelf 90.

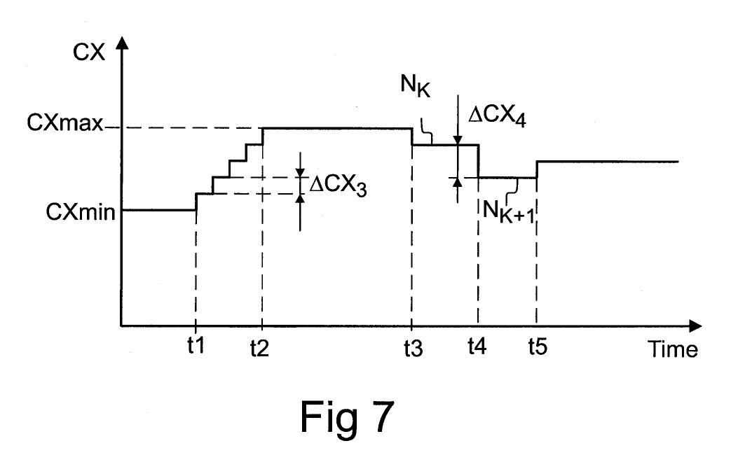

FIG. 7 shows evolution of the capacitance CX of a capacitive proximity sensor 50 when objects G1 are added and removed e.g. to/from the area A1 of FIG. 3 or FIG. 6a.

If the shelf 90 is completely empty, the capacitance CX is initially equal to its minimum value CXmin. Between the times t1 and t2, the user adds five substantially similar objects G1 onto the shelf 90, one at a time. CX is increased in five steps until the area A1 accommodates the maximum number of objects G1 and the capacitance CX reaches its maximum value CXmax.

A customer may subsequently remove an object G1 from the shelf 90 at the time t3. A customer may simultaneously remove two objects from the shelf at the time t4. A customer may return one object G1 back to the shelf at the time t5.

The filling factor N/Nmax may be estimated by using the equation

$$\frac{N}{N max} = \frac{CX - CX min}{CX max - CX min} \qquad ( 1 )$$

where N denote the number of objects or occupied sites, Nmax denotes the maximum number of objects or the maximum number allocated sites, CX denotes instantaneous capacitance, CXmin denotes minimum value of the capacitance CX and CX max denotes maximum value of the capacitance CX.

The number of objects can be estimated by using the equation

$$N = \frac{CX - CX min}{CX max - Cx min} N max \qquad ( 2 )$$

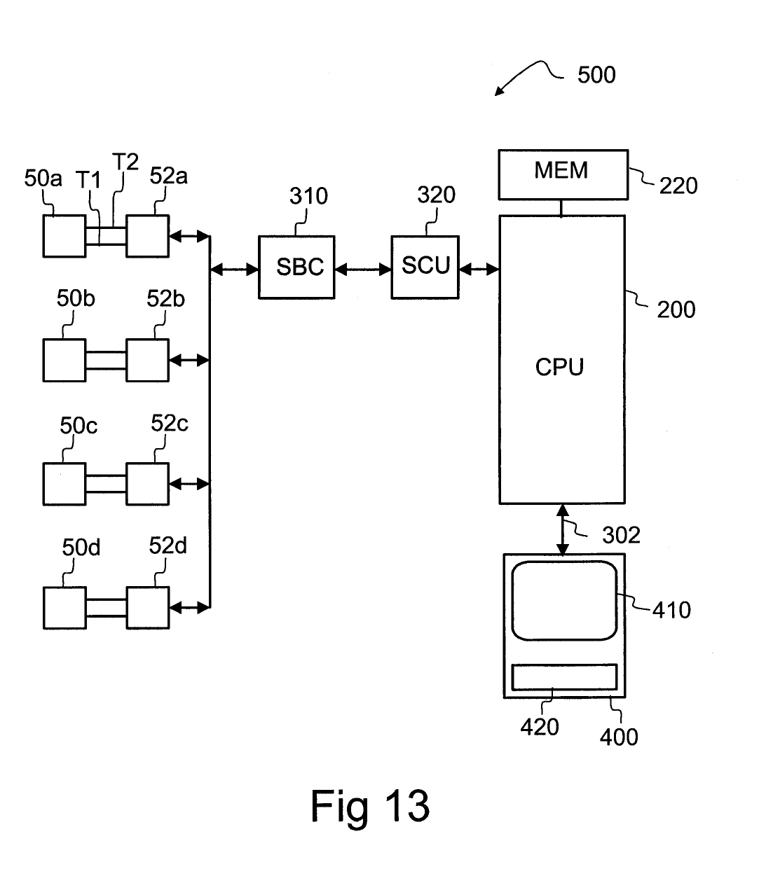

Nmax may be entered into the storage system 500 (FIG. 13) e.g. by the user, or Nmax may be retrieved from the system memory once the type of the objects G1, G2, G3 . . . has been indicated.

Each removal or addition of an object G1 is associated with a negative or positive change of CX.

If the magnitude of a first change ΔCX₃ of the capacitance CX associated with removal/addition of one object is known, the number of simultaneously removed/added objects may be determined by comparing a measured second change ΔCX₄ of the capacitance CX with said first change ΔCX₃.

In particular, said comparing may comprise dividing a measured second change ΔCX₄ of the capacitance CX by said first change ΔCX₃.

In case of FIG. 7, comparison of ΔCX₄ with ΔCX₃ indicates that two objects has been removed at time t4.

Consequently, if an initial number N_{K} of objects G1 is known, the number N_{K+1} of said objects G1 may be later determined by adding the number of added objects G1 and by removing the number of removed objects from the initial number N_{K}.

It may be that the absolute values of CX, ΔCX₃, and ΔCX₄ are not known. In that case values derived from signals depending on the CX may be used.

Thus, the measurement may comprise:
determining a third value (ΔCX₃) dependent on the change of the capacitance (CX) of said first capacitive proximity sensor (50) caused by removal/addition of one or more objects (G1),
changing the number (N) of said objects (G1),
detecting a fourth value (ΔCX₄) dependent on a change of capacitance (CX) of said first capacitive proximity sensor (50) associated with said changing,
determining the number of removed/added objects (G1) by comparing said fourth value (ΔCX₄) with said a third value (ΔCX₃), and
determining a number (N_{K+1}) of said objects (G1) by subtracting/adding the number of removed/added objects (G1) from/to a previous number (N_{K}) of said objects (G1).

The presence of the customer's hand or fingers may also temporarily change the value of CX. These abnormal conditions may be ignored by digital signal processing when determining the filling ratio or a change of CX. For example, the storage system 500 (FIG. 12a) may be arranged to take only stable values of CX into consideration.

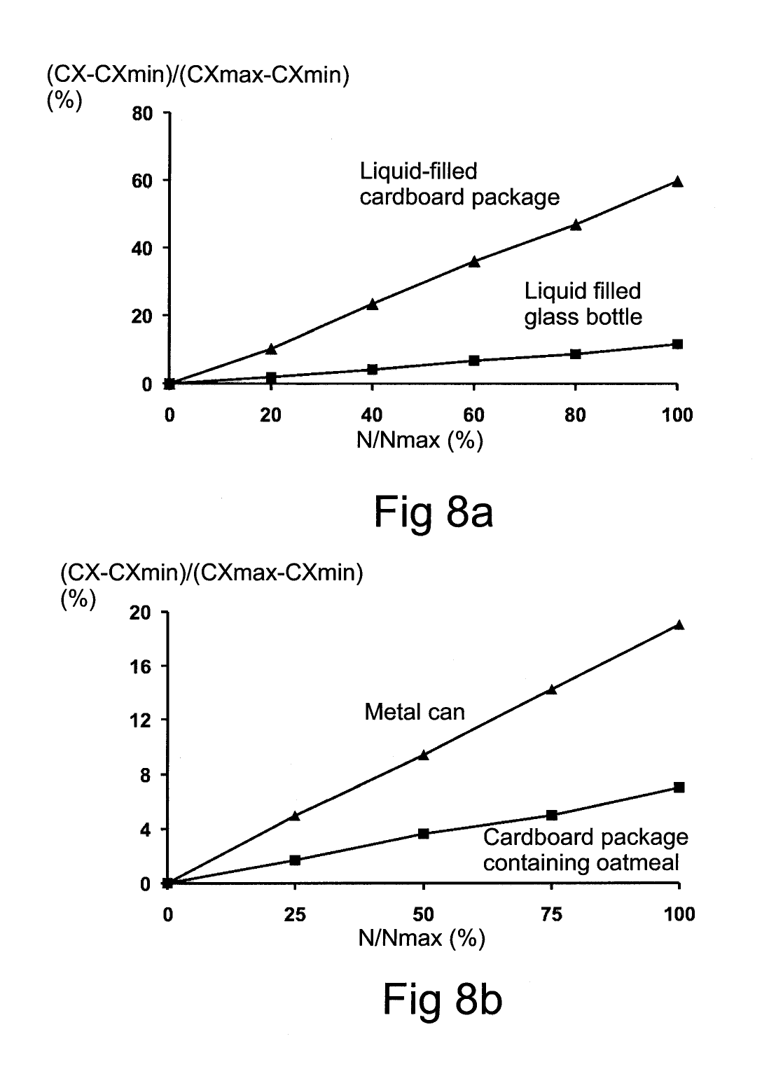

FIGS. 8a and 8b show experimentally measured values for the ratio (CX−CXmin)/(CXmax−CXmin) at various different filling factors. The upper curve in FIG. 8a is for tetrahedral cardboard packages containing juice. The packages are internally lined with electrically conductive aluminum foil. The lower curve in FIG. 8a is for glass bottles containing juice.

The upper curve in FIG. 8b is for metal cans containing crushed tomatoes. The lower curve in FIG. 8b is for cardboard packages containing oatmeal. It may be noticed that the relationship between the capacitance CX and the filling factor N/Nmax may be substantially linear.

It may be noticed that metal objects, i.e. electrically conductive objects typically cause a larger change in the capacitance CX than electrically insulating objects. Products containing water typically cause a larger change in the capacitance CX than dry products, due to the high permittivity of water.

In case of FIGS. 8a and 8b, the standard deviation of results was less than 1% when the experiment was repeated five times, i.e. the all objects were removed and added onto the sensor five times.

In case of FIGS. 8a and 8b, the accuracy of the measured filling ratio may be e.g. in the order of ±5%.

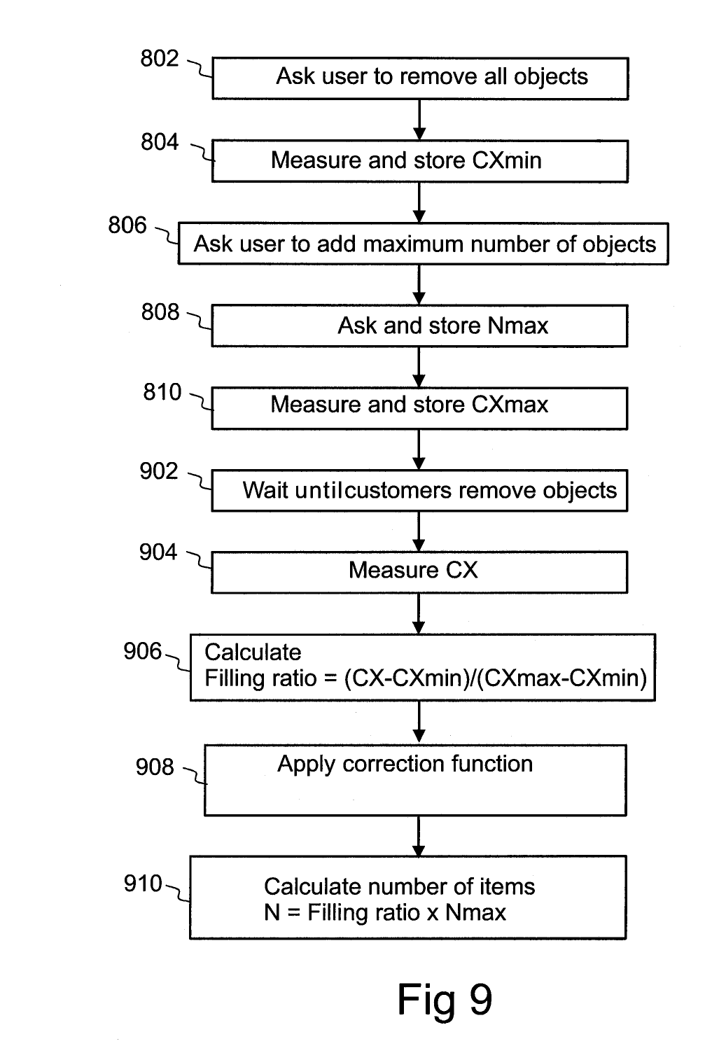

FIG. 9 shows a flow chart of a method for monitoring a storage unit 100. In step 802, the user (or a robot, see FIG. 12b) may be asked to remove all objects from an area A1. After all objects have been removed, the minimum value CXmin of the capacitance CX may be measured and stored into a memory 220 (FIG. 13) of a storage system 500 in step 804.

In step 804, the user is asked to add maximum number of objects to the area A1. The user is also asked to enter the maximum number NMax in step 808. Nmax may be stored into the memory 220.

After the maximum number of objects have been added, the maximum value CXmax of the capacitance CX may be measured and stored into the memory 220.

In step 902 customers may remove or return objects from/to the area A1. The capacitance CX is subsequently measured in step 904. The filling ratio is calculated in step 906 based on the measured value of CX and based on the minimum value CXmin and maximum value CXmax retrieved from the memory 220.

The number N of objects on the area A1 may be calculated in step 910.

It may be that the relationship between the actual filling ratio and the capacitance CX is not perfectly linear. It may be that the filling ratio estimated in step 906 deviates from the actual filling ratio.

Step 908 represents optional linearization. A correction function Func may be determined e.g. experimentally or theoretically for a specific type of objects G1 and/or for a specific sensor. The correction function may be stored in the memory 220. The filling ratio calculated in step 906 may be corrected in step 908 by using the correction function Func. The function Func may e.g. receive the filling ratio calculated in step 906 as an input value and provide a corrected filling ratio as an output value.

As an additional step, the data processor 200 may also be arranged to send an indication to the user interface if the determined filling ratio exceeds 100%. This may indicate e.g. that a customer has returned a wrong object to the shelf 90.

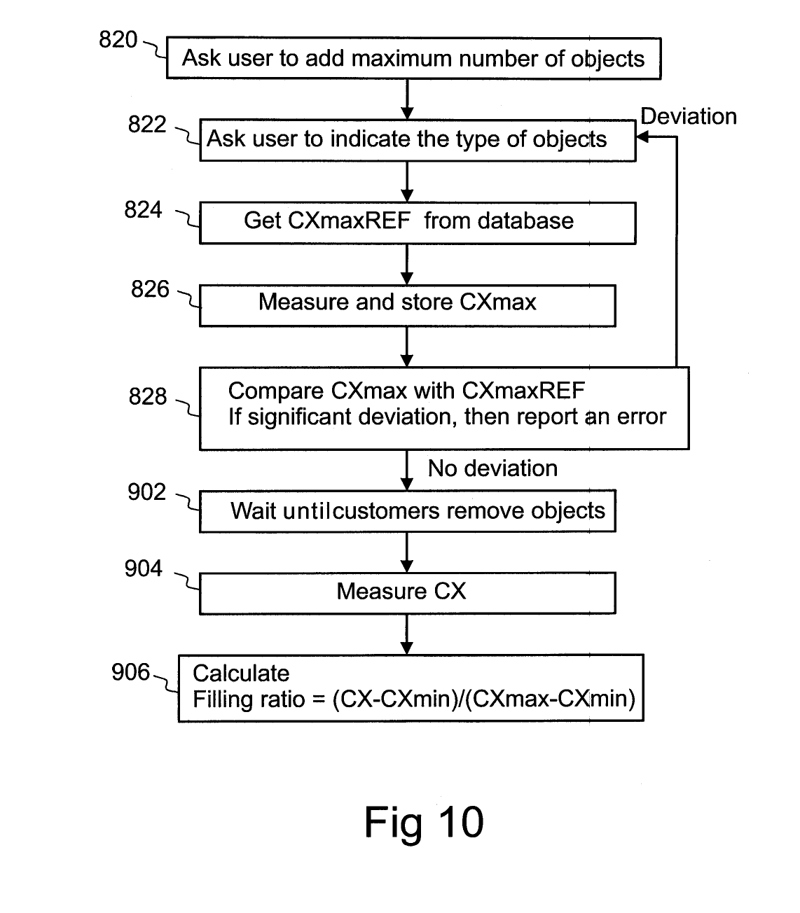

FIG. 10 shows a flow chart of another method for monitoring the storage unit 100. Removing all objects from the area A1 may be time-consuming. The minimum value Cxmin may also be retrieved from a memory, if it is previously known or estimated by other means.

In step 820, the user is asked to add maximum number of objects to the area A1. In step 822, the user may also be asked to indicate or confirm the type of the object associated with the area A1.

Now, the maximum value CXmax corresponding to the objects G1 may be retrieved from the memory 220 (step 824). CXmaxREF denotes the value of CX retrieved from the memory. The maximum value CXmax can also be measured in step 826, because the area A1 is now full of objects G1.

In step 828, a reliability check can be made. If the measured value CXmax significantly deviates from the value CXmaxREF retrieved from the memory, this may indicate that the type of the object indicated by the user does not match with the values retrieved from the database. In this case, the storage system may be arranged to report an error. The user may also be asked e.g. to indicate the correct type of the objects.

The steps 902, 904, and 906 may be executed as in case of FIG. 9.

FIG. 10 shows a flow chart of yet another method for monitoring the storage unit 100. The system may also be calibrated by adding or removing only a single object G1 (or by adding and/or removing at least one object G1). If the number of objects removed or added is Nmax, then the method will be similar to the case shown in FIG. 9.

In step 840, the user may be asked to indicate or confirm the type of the object G1 or to identify the area A1 where the calibration is performed. In step 842, the user may be asked to indicate the number of objects G1 currently on the area A1.

The user may also be asked to indicate the maximum number Nmax of objects G1 for the area A1. However, Nmax may also be retrieved from the memory 220.

The capacitance CX of the sensor 50 is measured and stored in step 844. In step 846, the user is asked to remove or add one object G1. The corresponding change of the capacitance ΔCX₃ is determined in step 848 and stored into the memory.

The maximum value CXmax of the capacitance CX may be calculated in step 850, based on the known values of N, Nmax and ΔCX₃.

The minimum value CXmin of the capacitance CX may be calculated in step 852, based on the known values of N, Nmax and ΔCX₃.

If corresponding values of CXmax and/or CXmin have been previously stored in the memory (e.g. by the calibration method of FIG. 9), the calculated value of CXmax and/or CXmin may also be compared with the values retrieved from the memory in order to check the reliability of the calibration.

The steps 902, 904, and 906 may be executed as in case of FIG. 9.

FIG. 12a shows a block diagram of a storage system 500. The storage system 500 comprises one or more storage units 100. The storage system 500 comprises several capacitive proximity sensors 50a, 50b, 50c, 50d to monitor objects on areas A1, A2, A3, etc.

The storage system 500 comprises means for gathering capacitively measured data from the sensors, and means for making the data available to an information system.

The terminals T1, T2 of the sensors 50a, 50b, 50c, 50d may be coupled to read-out units 52a, 52b, 52c, 52d. For example, the terminals T1, T2 of a sensor 50a, may be coupled to a read-out unit 52a.

The read-out unit 52a may be arranged to provide a signal which depends on the capacitance CX of the sensor 50a. The read-out unit 52a may comprise e.g. an impedance-measuring circuit. The capacitance value CX may be measured by coupling an alternating voltage to the capacitor CX, and by determining the impedance of said capacitor.

The read-out unit 52a may comprise a switched capacitor which transfers charge to or from the sensor 50. The switched capacitor charges or discharges the sensor 50 at reproducible rate. In that case the rate of change of the voltage over the terminals T1, T2 depends on the capacitance value CX of the sensor 50.

The capacitance value CX may also be measured by coupling the sensor 50 as a part of an RC-circuit, and by determining the time constant of said RC-circuit. The resistor and the capacitor CX are connected in series, and the capacitor CX is charged through the resistor, starting from a defined voltage. The charging time can be characterized with the time constant. The time constant of the circuit, formed by the capacitor and the resistor, is determined either by measuring the time until a predetermined voltage level is reached or by measuring the voltage after a predetermined loading time. When the time constant and the resistance are known, the capacitance can be calculated.

The capacitance value CX of the sensor 50 may also be detected by coupling said capacitor CX as a part of a tuned oscillation circuit.

The relationship between the capacitance CX and the signal may be linear or substantially linear. The signasl provided by the read-out units 52a, 52b, 52c, 52d may be digital signals.

Typically, there is no need to know the absolute value of the capacitance CX. However, in order to maximize reliability of the storage system 500, substantially all sensors 50a, 50b, 50c of the system may be checked by calibrating them with a common test object.

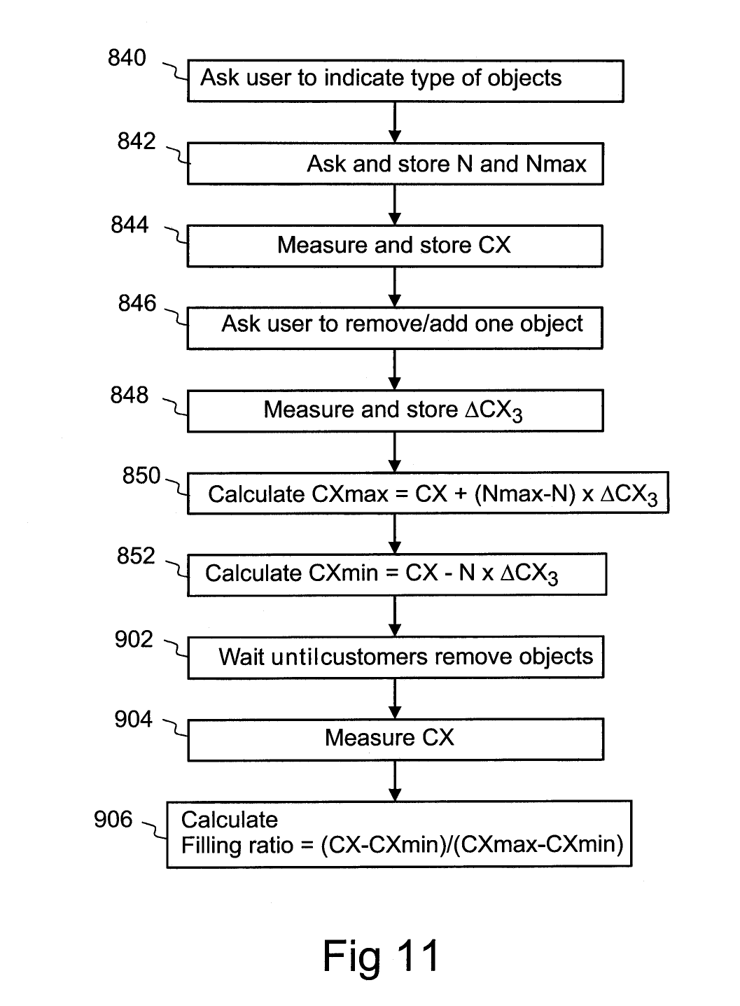

The signals provided by a plurality of read-out units 52a, 52b, 52c, 52d may be communicated via a data bus 301 to a data processing unit 200 (CPU). Measured and determined values may be stored and retrieved from a memory 220. The memory 220 may also comprise program code for executing the programs of e.g. FIGS. 9, 10 and 11.

The data processing unit 200 may communicate calculated and retrieved information to a user interface 400. The user interface 400 may comprise e.g. a graphical display 410 and/or an input device 420, e.g. a keyboard.

Also a mobile phone or a PDA may be used as a user interface 400.

If the filling ratio is smaller than equal to a predetermined limit (e.g. 50%), the data processing unit 200 may be arranged to send an indication to the user interface 400.

The information provided by the sensors may be used to make an inventory of objects in a retail store, even in real time.

The data processing unit 200 may also be arranged to calculate the rate of change of the filling ratio, or to determine a parameter which indicates the rate of change of the filling ratio. If the rate of change of the filling ratio is greater than a predetermined limit or smaller than a predetermined limit, the data processing unit 200 may be arranged to send an alarm to the user interface 400. If customers are buying the objects G1 at an exceptionally high rate, this may indicate that the indicated price is erroneously too low. If customers buy the objects G1 at an exceptionally low rate, this may indicate e.g. that the products are corrupted.

Referring to FIG. 12b, the storage system 500 may further comprise a robot 600 (ROBO), a cashing system 450 (CASH), and/or a security unit 460 (SECUR). The storage system 500 may be arranged to communicate with a manufacturer 700 (MNF) of the objects G1, with the robot 600, with the cashing system 450 (CASH), and/or the security unit 460. The communication may take place via paths 302, 303, 304, 305, and/or 306.

If the filling ratio is smaller than equal to a predetermined limit (e.g. 25%), the data processing unit 200 may be arranged to send a command to a robot 600 (ROBO). The robot may be arranged to fetch more objects from a depot according to said command.

The cashing system 450 may be arranged to provide information about the number of sold items G1. The storage system 500 may be arranged to provide information about the number of objects taken away from a storage unit 100. The storage system may be arranged to compare these numbers.

For example, the storage system 500 may be arranged to send an alarm to a security unit 460 if the number of sold objects significantly deviates from the number of objects taken away from the storage unit 100 within a predetermined time period. The time period may be e.g. one day. The security unit 360 may e.g. graphically display an alarm to the security personnel and indicate the type of the objects G1 and/or the areas A1, A2, A3 where said objects are located. Thus, the security personnel may pay special attention to the areas A1, A2, A3 (FIG. 6a). For example, the number of security personnel patrolling near the areas A1, A2, A3 may be increased, and/or video recordings related to the areas A1, A2, A3 may be scrutinized in order to identify a thief or another reason for the deviation.

The storage system 500 may be arranged to compare the number of objects G1 supplied by the manufacturer 700 with the number of objects G1 added to the storage units 100. The storage system 500 may be arranged to send an indication to the user interface 400 if there is a deviation.

If the filling ratio is smaller than equal to a predetermined limit (e.g. 50%), the data processing unit 200 may be arranged to order more objects from a manufacturer 700 (MNF). If the filling ratio exceeds a predetermined limit, the data processing unit 200 may be arranged to delay or cancel an order.

The electrical properties of the sensors and the read-out units may drift as a function of time, temperature and/or humidity. In order to compensate the drift, at least one of the sensors (e.g. 50d) may be used as a reference sensor. The reference sensor may be arranged such that customers can not move objects in the vicinity of the reference sensor.

The read-out unit may also comprise a reference capacitor or a “dummy pin” in order to compensate drift. The read-out unit may be arranged to monitor the capacitance CX of an actual sensor 50 and the capacitance of the reference capacitor alternately.

The signals may be communicated via the data bus or data buses 310, 302, 303, 304, 305, 306. The bus(es) may be e.g. based on conductors, optical fibers, or radio frequency (wireless) communication, e.g. on the bluetooth standard.

The storage units 100 may further comprise further sensors or transducers, e.g. temperature sensors, humidity sensors or leak sensors to monitor the environmental conditions in the vicinity of the objects G1. These further transducers may be e.g. attached onto the shelves. The information provided by said transducers may also be communicated via the data bus 301.

When the storage units 100 comprise shelves, the storage system 500 may also be called as a shelf measurement system.

Referring to FIG. 13, the storage system 500 may further comprise a sensor bus converter 310 (SBC) and a sensor control unit 320 (SCU). The sensor control unit 320 may be arranged to receive measured information from several sensor read-out units 52a, 52b, 52c and to control the operation of the read-out units 52a, 52b, 52c. The sensor bus converter 310 may be arranged to act as an interface between several read-out units 52a, 52b, 52c and the sensor control unit 320.

Each shelf 90 may comprise one sensor 50a and a read-out unit 52a. A shelving (see e.g. FIG. 6a) may comprise e.g. nine sensors and read-out units.

The sensor control unit 320 may be arranged to communicate with the data processing unit 200. The data processing unit 200 may comprise the sensor control unit 320.

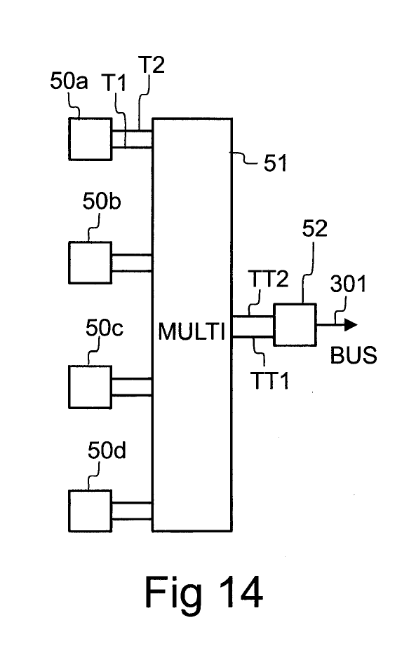

The sensors 50a, 50b, 50c may comprise e.g. aluminum foil laminated between plastic foils. The read-out unit 52 comprises electronics, which may be more expensive. It may be economically feasible to combine several sensors 50a, 50b, 50c to a single read-out unit by multiplexing. Referring to FIG. 14, the terminals T1, T2 of several sensors 50a, 50b, 50c, 50d may be connected to a single read-out unit 52 by an analog multiplexer 51 (MULTI). The multiplexer 51 may be arranged to sequentially couple each pair of the electrodes 10, 20 of the sensors 50a, 50b, 50c to the inputs TT1, TT2 of the read-out unit 52.

The multiplexer 51 may be arranged to send identity information which associates the capacitively measured signal generated by using an electrode pair 10, 20 with the identity and/or location of said electrode pair 10, 20.

The timing of the operation and the scanning speed of the multiplexer 51 may be controlled e.g. by the sensor control unit 320 or the sensor bus converter 310.

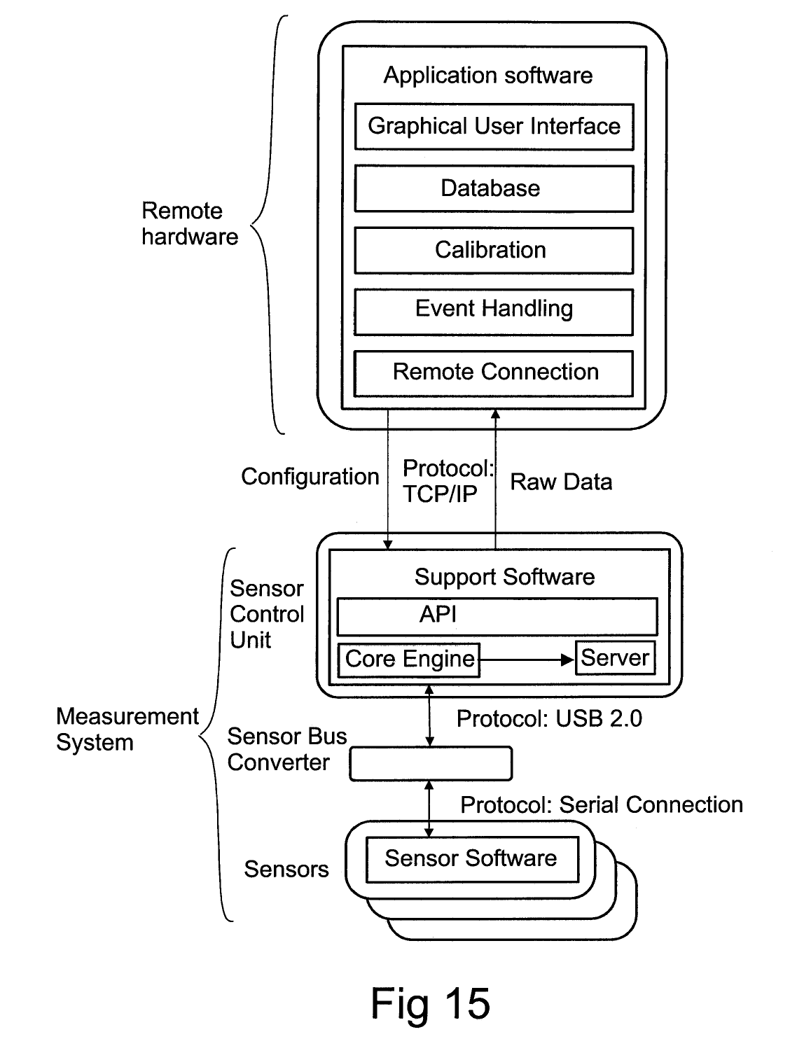

FIG. 15 shows software levels of the storage system 500. An application software, i.e. computer program may be running on a remote hardware, e.g. on the data processing unit 200. The application software may comprise code for operating a graphical user interface 400, for managing data in the database e.g. in the memory 220, for calibrating sensors 50 (see the discussion related to FIGS. 9-11), for monitoring events (e.g. detecting removal of objects G1 by customers), and for communicating with e.g. one or more sensor control units 320.

The remote hardware may communicate with a sensor control unit 320 e.g. by TCP/IP protocol (Transmission Control Protocol/Internet Protocol).

The sensor control unit 320 may be configured by sending instructions from the remote hardware. The sensor control unit 320 may send raw measured data to the remote hardware.

A support software, i.e. computer program may be running on the sensor control unit 320. The support software may comprise code for Application Programs Interface (API), for a core engine, and for a server.

The sensor control unit 320 may receive measured data from the read-out units 52 of the sensors 50 via a sensor bus converter 310. The sensor control unit 320 may communicate with the sensor bus converter 310 e.g. by universal serial bus, e.g. by USB 2.0. The sensor bus converter 310 may communicate with the rear-out units by serial connection.

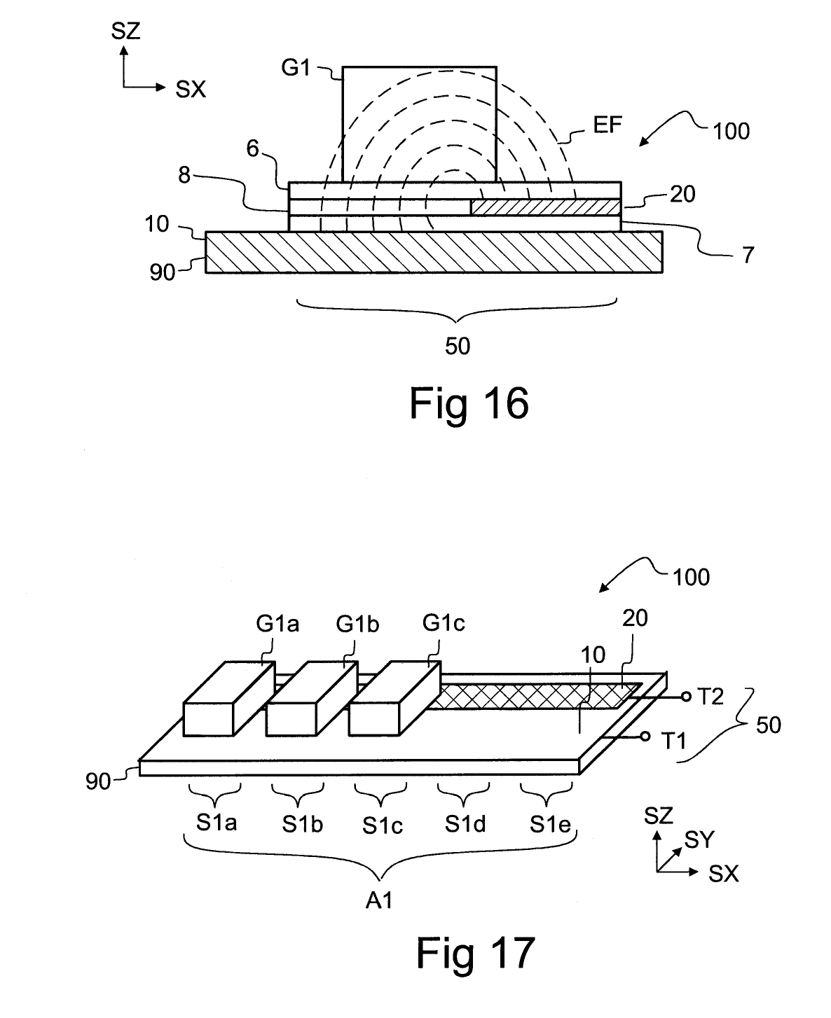

FIGS. 16 and 17 show a sensor 50 where an electrically conductive surface of a metal shelf 90 is arranged to act as the reference electrode. Thus, the material consumption for implementing the electrodes of the sensors 50 may be reduced. However, in this case an electrical connection to the shelf 90 should be implemented. In other words, a terminal T1 should be electrically connected to the metal shelf 90. Instead of the shelf 90, another large electrically conductive structure of the storage unit 100 may be used. The structure may comprise a filler plate 8.

FIG. 18a shows a storage unit 100 comprising several independent sensors 50a, 50b, 50c, 50d, 50e to detect each object G1a, G1b, G1c separately. Thus, objects G1 on each site S1a, S1b, S1c, S1d, S1e may be detected separately.

Each sensor 50a, 50b, 50c, 50d, 50e comprises two electrodes 10a, 20a, 10b, 20b, 10c, 20c, 10d, 20d, 10e, 20e, and each electrode comprises at least one terminal T1a, T2a, T1b, T2b, T1c, T2c, T1d, T2d, T1e, T2e. The first sensor 50a comprises electrodes 10a, 20a. The electrode 10a has a terminal T1a, and the electrode 20a has a terminal T2a.

Individual monitoring of each site may provide high accuracy when the area of each site is selected to accommodate a single object G1. The storage unit 100 may comprise guide means arranged to define the location of the objects G1a, G1b, G1c with respect to the sensors 50a, 50b, 50c, 50d, 50e. The guide means may be e.g. rods or vertical plates which ensure that the objects are not positioned to an area which is between two adjacent sensors. The guide means may also be e.g. visual indicators, e.g. colored lines, which indicate the allowable positions of the objects G1a, G1b, G1c.

FIG. 18b shows a storage unit 100 where each site is individually monitored, but e.g. the electrode 20a is shared between a first sensor 50a, and a second adjacent sensor 50b. The signal electrode 20a of sensor 50a may also act as a reference electrode 10b or signal electrode of the sensor 50b. In this way the number of the terminals and wires may be reduced when compared with the unit 100 of FIG. 18a. However, the sensitivity may be low for objects positioned near the center of the electrode 20a. Also in this case the storage unit 100 may comprise guide means arranged to define the location of the objects G1a, G1b, G1c with respect to the sensors 50a, 50b, 50c, 50d, 50e.

FIG. 18c shows yet another storage unit 100 where the electrically conductive metal shelf acts as a common reference electrode 10 for all sensors 50a, 50b, 50c, 50d, 50e. The first sensor 50a comprises a signal electrode 20a and the common reference electrode 10. The second sensor 50b comprises a signal electrode 20b and the common reference electrode 10. The third sensor 50c comprises a signal electrode 20c and the common reference electrode 10. The fourth sensor 50d comprises a signal electrode 20d and the common reference electrode 10. The fifth sensor 50e comprises a signal electrode 20e and the common reference electrode 10. The sensors 50a, 50b, 50c, 50d, 50e may be arranged to individually monitor each site S1a, S1b, S1c, S1d, S1e. Also in this case the storage unit 100 may comprise guide means arranged to define the location of the objects G1a, G1b, G1c with respect to the sensors 50a, 50b, 50c, 50d, 50e.

Thus, the amount of conductive foil and the number of wires may be further reduced when compared to FIGS. 18a and 18b.

However, the number of wires and the number of read-out units may be even further reduced by configuring each sensor to simultaneously detect several objects, as in case of FIGS. 3 and 6a.

The user may change the allocation of the sites. For example, the user may decide that the site S1c should be allocated for objects G2 instead of the objects G1. In other words, the left hand side of the area A2 and the right hand side of the area A1 should be shifted to the left. The definition of the areas A1 may be made e.g. by using the user interface 400.

However, also another phenomenon may be used. Movement of the objects G1 in the vicinity of the sensors 50 may cause transient variations in the capacitance CX, which may be easily detected by signal processing electronics, e.g. by the data processor 200 or by the read-out unit 52. In particular, touching of the sensor 50 by a hand or finger may cause clearly identifiable variations. This phenomenon may be used for communicating with the storage system 500.

For example, the user may define the area A1 reserved for the objects G1 simply by tapping the sensors 50a and 50c on FIG. 18c with his finger.

Thus, defining the area A1 or sites S1a, S1b, S1c reserved for the objects of type G1 may comprise:
identifying the type of the objects G1 or the area A1 e.g. by an user interface 400, and
moving an object, objects or a finger in the vicinity of the sites S1a, S1b, S1c allocated for said objects G1.

Alternatively, defining the area A1 or sites S1a, S1b, S1c reserved for the objects of type G1 may comprise:
identifying the type of the objects G1 or the area A1 e.g. by an user interface 400, and
moving an object or finger in the vicinity of an edge of said area A1.

The sensor 50 or sensors of a storage unit 100 may also be arranged to provide location information. For example, the storage unit 100 may comprise two or more independent sensors 50a, 50b, 50c, 50d, 50e, wherein a first sensor 50a may have reduced sensitivity to objects in the vicinity of a second sensor 50b.

FIG. 19 shows a shelf 90 where a sensor 50 is positioned near the front edge of the shelf 90. Thus, the storage unit 100 comprising said shelf 90 has reduced sensitivity to objects G1 near the back side of the shelf 90. Thus, the sensor 50 may be arranged to monitor the filling factor of objects G1 in an area A11 near the front side of shelf. The storage system 500 may be arranged to alert the personnel that the filling factor of the front area A11 is too low.

The low filling factor of the front area A11 may be a problem although the filling factor of the back area A12 would be high. Customers tend to pick up items G1 from the front area A11 of the shelf 90, and they collect items from the back area A12 only after the front side is substantially empty. This may make the appearance of the goods G1 less appealing and may reduce sales of the objects G1. Supermarket personnel may spend substantial time on shifting items from back side of the shelves to the front.

The shelf 90 may also comprise a second sensor to monitor objects G1 on the back area A12 of the shelf 90. The storage system 500 may be arranged to determine the filling factor of a front area A11 of a storage unit 100 and the filling factor of a back area A12 of a storage unit separately.

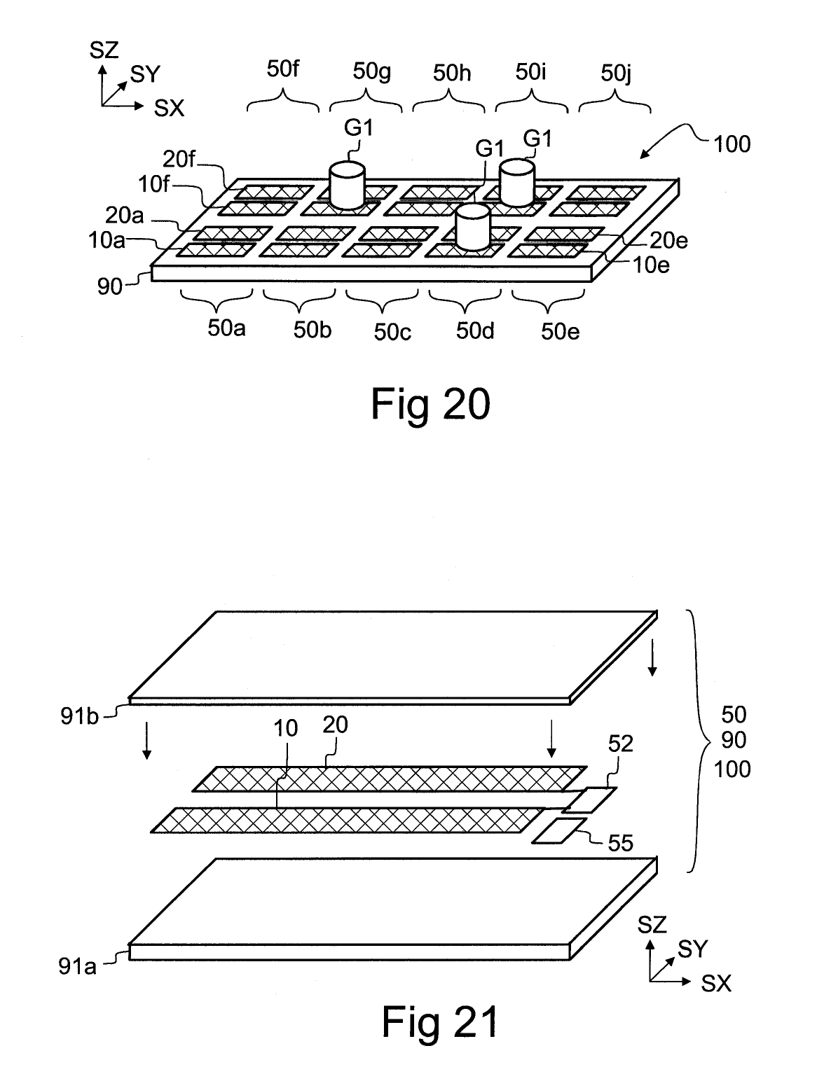

Referring to FIG. 20, the shelf 90 may comprise e.g. the substantially independent sensors 50a, 50b, 50c, 50d, 50e, 50f, 50g, 50h, 50i, and 50j arranged as an 2×5 array, in general in an 2×M array, were M is an integer. The first sensor 50a has electrodes 10a, 20a. The sensor 50e has electrodes 10e, 20e, and the sensor 50f has electrodes 10f, 20f. Also the other sensors have their electrodes, respectively. The storage unit 100 of FIG. 18a, 18b, 18c, or 20 may be arranged to provide location information, e.g. that the objects G1 are positioned on the sensors 50d, 50g, 50i, but not on the sensors 50a, 50b, 50c, 50e, 50f, 50h, and 50j.

A sensor unit may comprise several individual sensors 50a, 50b, 50c, 50d, 50e. The sensors 50a, 50b, 50c, 50d, 50e may be implemented in or on a common substrate 7.

The sensor unit may be e.g. a laminated structure which attached onto a shelf 90 by using glue, magnets or tape.

The electrode 20a may be e.g. slightly less than 50 mm wide in the direction SX. Thus, a shelf 90 which is 900 mm wide in the direction SX may comprise e.g. 18 (=N_{E}) individual electrodes, which may be arranged to individually monitor up to 17 (N_{E}−1) sites S1a, S1b, S1c.

Several sensors 50a, 50b, 50c may also be arranged to detect the presence of the same object G1, e.g. when the object G1 is large. This may provide improved reliability. For example, if the object G1 is substantially homogeneous, the signals provided by the sensors 50a, 50b, 50c should be of substantially equal magnitude. A difference in the magnitudes indicates an error.

A shelf 90 which is 900 mm wide in the direction SX and whose depth is 400 mm in the direction SY may comprise e.g. 18 electrodes arranged as a 9×2 array. The dimensions of each electrode 10, 20 may be e.g. slightly less than 100 mm×200 mm. Electrodes near the front edge of the shelf 90 may be used as the reference electrodes 10a, 10b, 10c, and the electrodes near the back side may be used as the signal electrodes 20a, 20b, 20c, respectively.

The sensor 50 may also comprise a plurality of reference electrode areas and a plurality of signal electrode areas arranged as a two-dimensional array, e.g. in a chessboard formation.

The electrodes 10, 20 may be connected to the terminals T1, T2 by conductors. However, the electrodes 10, 20 may itself act as the conductors and/or terminals. The electrodes and the conductors may be e.g. etched on a laminated metal foil, or printed with a conductive ink. The substrate 7 may be flexible, e.g. polyester film. The substrate 7 may also be rigid, e.g. glass, plastics, ceramics, or composite material, e.g. glass fiber epoxy laminate.

The electrodes 10, 20 may be embedded inside a shelf 90 by printing the electrode patterns 10, 20 directly on the shelf board (e.g. on a medium density fiberboard) e.g. with a screen printer with a conductive ink or paste (e.g. silver paste), conductive polymer (e.g. poly-3,4-ethylenedioxythuophene), or carbon paste.

For example, the patent publication WO 2006/003245 discloses sensor products and laminated electrodes suitable for implementing a sensor 50.

For example, the patent publication WO 2008/068387 discloses a continuous web comprising several electrodes whose conductors have been arranged to cross a common line in order to facilitate easy connection. The web of WO 2008/068387 can be used to implement a sensor 50.

The electrodes 10, 20 of the sensor 50 or sensors may be arranged e.g. in a spiral formation, as a two-dimensional array, as a three-dimensional array, above the objects, under the objects, behind the objects, or on both sides of the objects.

The distance between a sensor 50 and the read-out unit 52 may be e.g. less than 0.5 m in order to reduce signal noise. The read-out unit 52 may be inserted e.g. into a cavity in a shelf board.

A read-out unit 52a may comprise a switched reference capacitor C_{S} to monitor the capacitance CX of the sensor 50. Examples for such a read-out unit have been disclosed e.g. in a patent application PCT/FI2008/050379.

Thus, a read-out unit 52a may comprise:
a voltage supply,
a first switch to couple the reference capacitor to said voltage supply in order to charge said reference capacitor,
a tank capacitor CX,
a second switch to couple said reference capacitor to said tank capacitor CX in order to transfer charge from said reference capacitor to said tank capacitor CX and to change the voltage of said tank capacitor CX,
at least one switch driver unit to control said charging and charge transfer by opening and closing said switches several times such that said switches are not in the closed state simultaneously,
a voltage monitoring unit to monitor the voltage of said tank capacitor CX, and
a controller to determine at least one measurement value which depends on the rate of change of the voltage of said tank capacitor CX.

The capacitance of the tank capacitor CX may be e.g. greater than or equal to 10 times the minimum capacitance value of the reference capacitor, preferably greater than or equal to 100 times the capacitance value of said reference capacitor.

The voltage of the tank capacitor may be increased by closing and opening the first and second switches consecutively several times until the voltage reaches or exceeds the reference voltage provided by a reference voltage source 58.

The switching rate of the first and second switches may be controlled e.g. by the data processing unit 200 in order to optimize data acquisition rate with the dielectric properties of the detected objects G1.

The voltage of the reference capacitor represents a low-energy signal, and the voltage of the tank capacitor represents a high-energy signal. Transferring charge to a larger known capacitor by the smaller reference capacitor makes it possible to integrate the low energy signal into the high energy signal before e.g. analog-to-digital conversion. Consequently, the sensitivity of the measuring device to electromagnetic interferences is considerably reduced. The combination of the sensor 50a, and the read-out unit 52a comprises a low pass filter, which is formed from the smaller reference capacitor, a charge-transferring switch and the larger tank capacitor. Said low-pass filter effectively attenuates noise cause by high frequency interference.

FIG. 21 shows making of a shelf 90 which comprises an integrated sensor or sensors 50. The electrodes 10, 20 may be e.g. laminated between a lower plate 91a and an upper plate 91b. At least one of the plates 91a, 91b may be of an electrically insulating material. The length of the resulting shelf 90 may be e.g. greater than 600 mm, and the resulting shelf may be rigid enough to be used as a shelf for support e.g. a load of at least 20 kg, when the shelf is supported e.g. from the left and right sides.

A read-out unit 52 and/or further sensors 55 may be integrated into or on the structure. The further sensor 55 may be e.g. a temperature sensor or a humidity sensor arranged to send information e.g. to the data processor 200.

The sensor 50 (or a sensor unit comprising several sensors 50) may also be a relatively stiff planar element which is positioned on a shelf 90. This kind of a sensor 50 may also be manufactured by laminating the electrodes 10, 20, conductors and possibly also a read-out unit 52 between a substrate 7 and an insulating layer 6 (FIG. 1). The sensor 50 may be held on its place primarily by gravity. The size and (or form of the sensor 50 may match with the size and/or form of the shelf 90.

Referring back to FIG. 6a, It may be advantageous that sensors arranged to detect objects G3 on the area A7 have minimum sensitivity to objects G4 on the adjacent area A8. The storage unit 100 may comprise grounding electrodes or structures to isolate adjacent sensors 50 from each other.

The determined filling ratio or the number of occupied sites may be used to implement a “kanban” or “two box” storage management system. If the filling factor is less than or equal to 50%, or if more than half of the sites are empty, the storage system 500 may be arranged to send an order to replenish the storage unit 100.

The capacitive proximity sensor 50 may be used in conditions where acceleration or vibration is present. For example, the capacitive proximity sensor may be used in retail stores which are located in boats, e.g. in luxury ships.

The word “comprising” is to be interpreted in the open-ended meaning, i.e. a sensor which comprises a first electrode and a second electrode may also comprise further electrodes and/or further parts.

For a person skilled in the art, it will be clear that modifications and variations of the devices and the method according to the present invention are perceivable. The particular embodiments and examples described above with reference to the accompanying drawings are illustrative only and not meant to limit the scope of the invention, which is defined by the appended claims.

1. A method for monitoring the number (N) or filling ratio (N/Nmax) of objects (G1) stored by a storage unit (100), wherein said storage unit (100) has sites (S1a, S1b) for accommodating two or more of said objects (G1), said method comprising detecting the presence of said objects (G1) in the vicinity of said sites (S1a, S1b) by using one or more capacitive proximity sensors (50).

2. The method of claim 1 wherein said storage unit (100) comprises a first capacitive proximity sensor (50) arranged such that the capacitance (CX) of said first capacitive proximity sensor (50) depends on the number (N) of sites (S1a, S1b) occupied by said objects (G1).

3. The method of claim 2 comprising calibrating said storage unit (100) by:—removing all objects (G1) from said sites (S1a, S1b),
storing a first value (CXmin) dependent on the capacitance (CX) of said first capacitive proximity sensor (50) when all said sites are empty,
inserting an object (G1) to each of said sites (S1a, S1b), and
storing a second value (CXmax) dependent on the capacitance (CX) of said first capacitive proximity sensor (50) when all said sites are occupied.

4. The method of claim 2 comprising calibrating said storage unit (100) by:
removing or adding at least one of said objects (G1), but less than the maximum number (Nmax) of said objects (G1), and
storing a third value (ΔCX3) dependent on the change of the capacitance (CX) of said first capacitive proximity sensor (50) caused by said removal/addition.

5. The method of claim 3 comprising:—removing or adding at least one of said objects (G1), but less than the maximum number (Nmax) of said objects (G1),
storing a third value (ΔCX3) dependent on the change of the capacitance (CX) of said first capacitive proximity sensor (50) caused by said removal/addition, —changing the number (N) of said objects (G1),
calculating a first filling ratio (N/Nmax) based on said first value (CXmin) and said second value (CXmax),
calculating a second filling ratio (N/Nmax) based on said third value (ΔCX),
comparing said first filling ratio with said second filling ratio, a significant deviation between said ratios indicating an error.

6. The method according to claim 2 comprising:
determining a third value (ΔCX3) dependent on the change of the capacitance (CX) of said first capacitive proximity sensor (50) caused by removal/addition of one or more objects (G1), —changing the number (N) of said objects (G1),
detecting a fourth value (ΔCX₄) dependent on a change of capacitance (CX) of said first capacitive proximity sensor (50) associated with said changing,
determining the number of removed/added objects (G1) by comparing said fourth value (ΔCX₄) with said a third value (ΔCX3), and—determining a number (N_{κ}+i) of said objects (G1) by subtracting/adding the number of removed/added objects (G1) from/to a previous number (N_{κ}) of said objects (G1).

7. The method according to claim 1 comprising correcting a determined number (N) or filling ratio (N/Nmax) by applying a correction function (Func).

8. The method according to claim 1 comprising comparing said filling ratio (N/Nmax) with a predetermined value, and sending an indication when the filling ratio (N/Nmax) is smaller than or equal to a predetermined value (50%).

9. The method according to claim 1 wherein said storage unit (100) is a shelving comprising shelves (90) in two or more levels.

10. The method according to claim 1 wherein said storage unit (100) is located in a retail shop, said storage unit (100) being accessible to customers.

11. A computer program arranged to perform the method according to claim 1.

12. A computer readable medium (220) comprising computer code, which when executed by a data processor (200) is for performing the method according to claim 1.

13. A storage system (500) comprising a storage unit (100), wherein said storage unit (100) has sites (S1a, S1b) for accommodating two or more of said objects (G1), said storage unit (100) further comprising one or more capacitive proximity sensors (50) arranged to detect the presence of said objects (G1) in the vicinity of said sites (S1a, S1b), said storage system (500) being arranged to determine the filling ratio (N/Nmax) or the number (N) of sites (S1a, S1b) occupied by said objects (G1) based on a signal or signals provided by said one or more capacitive proximity sensors (50).

14. The storage system (500) of claim 13 comprising a first capacitive proximity sensor (50) arranged such that the capacitance (CX) of said first capacitive proximity sensor (50) depends on the number (N) of sites (S1a, S1b) occupied by said objects (G1).

15. The storage system (500) of claim 13 comprising information about:
a first value (CXmin) dependent on the capacitance (CX) of said first capacitive proximity sensor (50) when all said sites (S1a, S1b) are empty, and
a second value (CXmax) dependent on the capacitance (CX) of said first capacitive proximity sensor (50) when all said sites (S1a, S1b) are occupied.

16. The storage system (500) according to claim 13 comprising information about a third value (ΔCX₃) dependent on the change of the capacitance (CX) of said first capacitive proximity sensor (50) caused by removal or addition of at least one of said objects (G1).

17. The storage system (500) according to claim 13 arranged to compare the determined filling ratio (N/Nmax) with a predetermined value (50%), and to send an indication when the filling ratio (N/Nmax) is smaller than or equal to said predetermined value (50%).

18. The storage system (500) according to claim 13 wherein said storage unit (100) is a shelving comprising shelves (90) in two or more levels.

19. The method according to claim 3 comprising:
determining a third value (ΔCX3) dependent on the change of the capacitance (CX) of said first capacitive proximity sensor (50) caused by removal/addition of one or more objects (G1), —changing the number (N) of said objects (G1),
detecting a fourth value (ΔCX₄) dependent on a change of capacitance (CX) of said first capacitive proximity sensor (50) associated with said changing,
determining the number of removed/added objects (G1) by comparing said fourth value (ΔCX₄) with said a third value (ΔCX3), and—determining a number (N_{κ}+i) of said objects (G1) by subtracting/adding the number of removed/added objects (G1) from/to a previous number (N_{K}) of said objects (G1).

20. The method according to claim 4 comprising:
determining a third value (ΔCX3) dependent on the change of the capacitance (CX) of said first capacitive proximity sensor (50) caused by removal/addition of one or more objects (G1), —changing the number (N) of said objects (G1),
detecting a fourth value (ΔCX₄) dependent on a change of capacitance (CX) of said first capacitive proximity sensor (50) associated with said changing,
determining the number of removed/added objects (G1) by comparing said fourth value (ACX₄) with said a third value (ΔCX3), and—determining a number (N_{κ}+i) of said objects (G1) by subtracting/adding the number of removed/added objects (G1) from/to a previous number (N_{K}) of said objects (G1).
